(19) United States
(12) Patent Application Publication
(10) Pub. No.: US 2026/0026313 A1
(43) Pub. Date: Jan. 22, 2026

(54) SEMICONDUCTOR PACKAGE, AND TEST METHOD AND RESCUE METHOD FOR THE SEMICONDUCTOR PACKAGE

(71) Applicant: Samsung Electronics Co., Ltd., Suwon-si (KR)

(72) Inventors: Youngguen SONG, Suwon-si (KR); Kyungyun PARK, Suwon-si (KR); Sangchol KIM, Suwon-si (KR)

(73) Assignee: Samsung Electronics Co., Ltd., Suwon-si (KR)

(21) Appl. No.: 19/058,360

(22) Filed: Feb. 20, 2025

(30) Foreign Application Priority Data
Jul. 16, 2024 (KR) 10-2024-0094006

(51) Int. Cl. H01L 21/66; H01L 23/00; H01L 23/62; H01L 25/18; H10B 80/00; H10D 80/30

(52) U.S. Cl. CPC H01L 22/22; H01L 22/34; H01L 23/62; H01L 24/08; H01L 25/18; H10B 80/00; H10D 80/30; H01L 24/16; H01L 2224/08146; H01L 2224/16227; H01L 2924/1431; H01L 2924/1436

(57) ABSTRACT

Provided are a semiconductor package of which yield may be improved through rescuing and a test method and a rescue method for the semiconductor package. The semiconductor package includes a base chip, a plurality of memory chips stacked on the base chip, and a deactivation controller configured to deactivate the memory chips, wherein the memory chips are classified into at least two stack-ID (SID) regions, each of the at least two SID regions includes a subset of the plurality (set number) of memory chips, and, when a fail-SID region including a failed memory chip, from among the at least two SID regions, exists, the deactivation controller is configured to deactivate all memory chips included in the fail-SID region, and activate memory chips in remaining SID regions other than the fail-SID region.

### CROSS-REFERENCE TO RELATED APPLICATION

This application is based on and claims priority under 35 U.S.C. § 119 to Korean Patent Application No. 10-2024-0094006, filed on Jul. 16, 2024, in the Korean Intellectual Property Office, the disclosure of which is incorporated by reference herein in its entirety.

### BACKGROUND

The inventive concepts relate to semiconductor packages, and more particularly, to semiconductor packages including stacked memory chips and test methods and rescue methods for the semiconductor package.

Due to the rapid development of the electronics industry and demands of users, electronic devices are becoming smaller and lighter. As electronic devices are becoming smaller and lighter, semiconductor packages used therein are also becoming smaller and lighter, and such semiconductor packages are desired to have higher reliability, higher performance, and larger capacity. To implement miniaturization, lighter weight, higher performance, larger capacity, and higher reliability, research and development are being continuously performed on semiconductor chips including TSVs and semiconductor packages in which the semiconductor chips are stacked in multiple layers.

### SUMMARY

Some example embodiments of the inventive concepts provide semiconductor packages of which yield may be improved through rescuing usable semiconductor chips and/or test methods and rescue methods of the semiconductor package.

Example embodiments of the inventive concepts are not limited to the disclosed example embodiments m, and other example embodiments may be clearly understood by one of ordinary skill in the art from the following descriptions.

According to an example embodiment of the inventive concepts, a semiconductor package includes a base chip, a plurality of memory chips stacked on the base chip, and a deactivation controller configured to deactivate the memory chips, wherein the memory chips are classified into at least two stack-ID (SID) regions, each of the at least two SID regions includes a subset of the plurality of memory chips, and when a fail-SID region including a failed memory chip, from among the at least two SID regions, exists, the deactivation controller is configured to deactivate all memory chips included in the fail-SID region, and activate memory chips in remaining SID regions other than the fail-SID region.

According to an example embodiment of the inventive concepts, a semiconductor package includes a base chip, a plurality of memory chips stacked on the base chip, and a fuse circuit configured to deactivate the memory chips, wherein the memory chips are classified into at least two stack-ID (SID) regions, each of the at least two SID regions includes four memory chips, and when a fail-SID region including a fail memory chip, from among the at least two SID regions, exists, the fuse circuit is configured to deactivate all four memory chips included in the fail-SID region, and activate memory chips in remaining SID regions other than the fail-SID region.

According to an example embodiment of the inventive concepts, a semiconductor package includes a package substrate, an intermediate substrate on the package substrate, a logic semiconductor devices on the intermediate substrate, and at least one first semiconductor package on the intermediate substrate and adjacent to the logic semiconductor device, wherein the first semiconductor package includes a plurality of memory chips classified into at least two SID regions, and a fuse circuit configured to deactivate memory chips in one SID region and activate memory chips in remaining SID regions.

According to an example embodiment of the inventive concepts, a test method of a semiconductor package includes in each of chip stacks formed by stacking a plurality of memory chips on a corresponding one of a plurality of base chips included in a wafer and performing a first test on each of the chip stacks, classifying the plurality of memory chips into at least two stack-ID (SID) regions in each of the chip stacks, when a chip stack that has passed the first test is referred to as a first chip stack and a chip stack that includes a fail-SID region including a failed memory chip, from among the at least two SID regions and has failed the first test is referred to as a second chip stack, deactivating all of the memory chips included in the fail-SID region through a fuse circuit, and performing a second test on the chip stacks, wherein the first test and the second test are tests for different characteristics, and the performing the second test includes performing the second test on some of the memory chips of each of the chip stacks, classifying chip stacks that have passed the second test into the first chip stack and the second chip stack, and performing the second test on remaining memory chips, other than the some of the memory chips, of each of first chip stacks.

According to an example embodiment of the inventive concepts, a rescue method of a semiconductor package includes in each of chip stacks formed by stacking a plurality of memory chips on a corresponding one of a plurality of base chips included in a wafer and performing a first test on each of the chip stacks, classifying the plurality of memory chips into at least two stack-ID (SID) regions in each of the chip stacks, when a chip stack that has passed the first test is referred to as a first chip stack and a chip stack that includes a fail-SID region including a failed memory chip, from among the at least two SID regions and has failed the first test is referred to as a second chip stack, deactivating all memory chips included in the fail-SID region and activating memory chips in remaining SID regions other than the fail-SID region through a first fuse circuit, performing a second test on the chip stacks, and changing the second chip stack that has passed the second test into a third chip stack, wherein the first test and the second test are tests for different characteristics, and the changing the second chip stack to the third chip stack includes reassigning an SID number of a SID region above the fail-SID region by using the first fuse circuit, and a chip-ID (CID) of memory chips within an SID region above the fail-SID region is changed by using a second fuse circuit.

According to an example embodiment of the inventive concepts, a test method of a semiconductor package includes in each of chip stacks formed by stacking a plurality of memory chips on a corresponding one of a plurality of base chips included in a wafer, performing a first test on each of the chip stacks classifying the plurality of memory chips into at least two stack-ID (SID) regions in each of the chip stacks, when a chip stack that has passed the first test is referred to as a first chip stack and a chip stack that includes a fail-SID region including a failed memory chip, from among the at least two SID regions and has failed the first test is referred to as a second chip stack, deactivating all memory chips included in the fail-SID region through a fuse circuit, and performing a second test on the chip stacks, wherein the first test and the second test are tests for different characteristics, and the performing the second test comprises performing the second test on some of the memory chips of each of the chip stacks, classifying chip stacks that have passed the second test into the first chip stack and the second chip stack, and performing the second test on remaining memory chips, other than the some of the memory chips, of each of first chip stacks.

The classifying the chip stacks into the first chip stack and the second chip stack includes classifying the chip stacks into the first chip stack and the second chip stack by using the fuse circuit, and a first pattern signal applied to the fuse circuit for classification has a phase opposite to that of a second pattern signal applied for determining normality of the fuse circuit.

The test method further includes before the deactivating, determining whether to deactivate the memory chips included in the fail-SID region, and before the performing of the second test, checking a program status of the fuse circuit.

According to an example embodiment of the inventive concepts, a rescue method for a semiconductor package includes in each of chip stacks formed by stacking a plurality of memory chips on a corresponding one of a plurality of base chips included in a wafer, performing a first test on each of the chip stacks, classifying the plurality of memory chips into at least two stack-ID (SID) regions in each of the chip stacks, when a chip stack that has passed the first test is referred to as a first chip stack and a chip stack that includes a fail-SID region including a failed memory chip, from among the at least two SID regions and has failed the first test is referred to as a second chip stack, deactivating all memory chips included in the fail-SID region and activating memory chips in remaining SID regions other than the fail-SID region through a first fuse circuit, performing a second test on the chip stacks, and changing the second chip stack that has passed the second test into a third chip stack, wherein the first test and the second test are tests for different characteristics, the changing the second chip stack to the third chip stack includes reassigning an SID number of an SID region above the fail-SID region by using the first fuse circuit, and a chip-ID (CID) of memory chips within an SID region above the fail-SID region is changed by using a second fuse circuit.

The performing the second test includes performing the second test on some of the memory chips of each of the chip stacks, classifying chip stacks that have passed the second test into the first chip stack and the second chip stack, and performing the second test on remaining memory chips of each of first chip stacks.

When each of the at least two SID regions comprises four memory chips, the second chip stack comprises 4(n+2) (n is an integer of 0 or more) memory chips, where n is an integer of 0 or more, and the changing the second chip stack to the third chip stack causes the third chip stack to operate identically to a fourth chip stack comprising 4(n+1) memory chips without a failed memory chip through deactivation and reassignment of the SID number by the first fuse circuit and changing of the CID by the second fuse circuit.

### BRIEF DESCRIPTION OF THE DRAWINGS

Example embodiments of the inventive concepts will be more clearly understood from the following detailed description taken in conjunction with the accompanying diagrams in which:

FIGS. 1A and 1B are a cross-sectional view and a conceptual diagram schematically showing a semiconductor package according to an example embodiment;

FIG. 1C is a conceptual diagram showing a comparison of the physical sizes of a high-stage semiconductor package and a low-stage semiconductor package;

FIG. 2 is a conceptual diagram schematically showing a semiconductor package according to an example embodiment;

FIGS. 3A to 3C are block diagrams showing a deactivation controller provided in a semiconductor package;

FIG. 4 is a conceptual diagram showing fuse-sets used in the deactivation controllers of FIGS. 3A to 3C;

FIG. 5A is a block diagram of a stack-ID (SID) fuse circuit within the deactivation controllers of FIGS. 3A to 3C;

FIG. 5B is a block diagram of a chip-ID (CID) fuse circuit within the deactivation controllers of FIG. 3C;

FIGS. 6A and 6B are a perspective view and a cross-sectional view of a semiconductor device including a semiconductor package;

FIG. 7 is a conceptual diagram showing a chip on wafer (CoW) package state in which a plurality of memory chips according to an embodiment are arranged on a wafer;

FIG. 8 is a schematic flowchart of a method of testing a semiconductor package, according to an example embodiment;

FIG. 9 is a schematic flowchart of a method of testing a semiconductor package, according to an example embodiment;

FIGS. 10A and 10B are flowcharts showing an operation of performing a second test in the method of testing a semiconductor package of FIG. 8 or FIG. 9 in more detail; and

FIG. 11 is a schematic flowchart of a method of rescuing a semiconductor package, according to an example embodiment.

### DETAILED DESCRIPTION

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

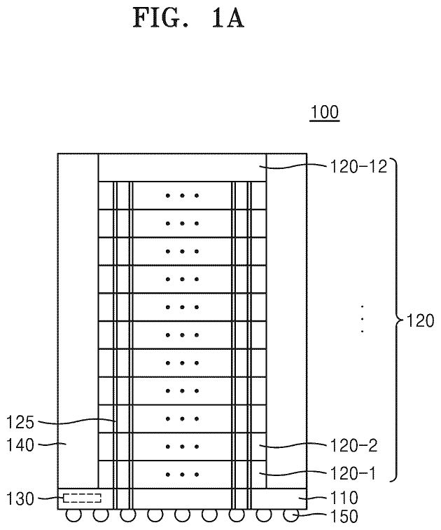

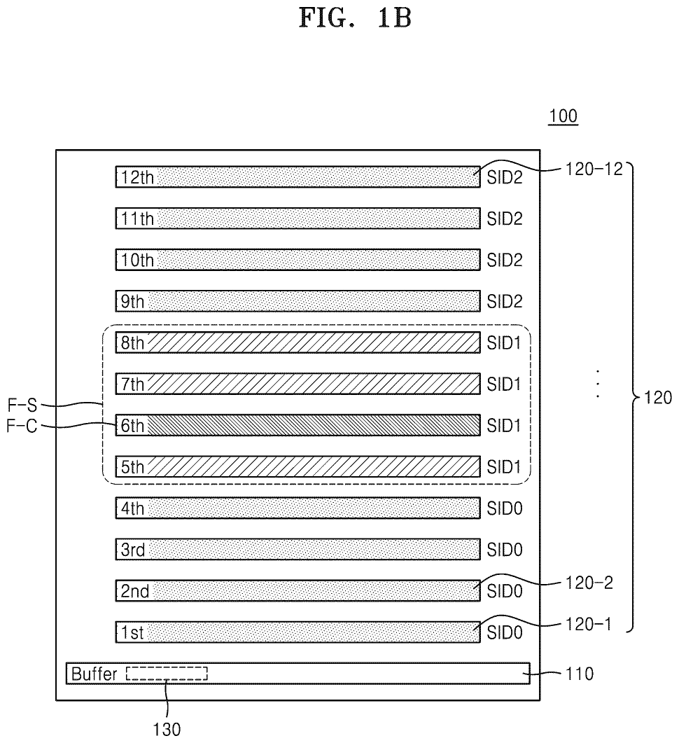

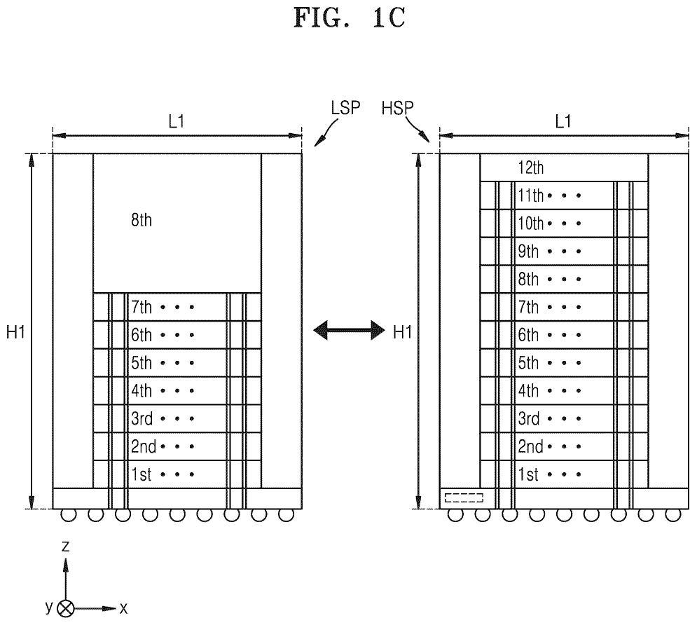

FIG. 1A and FIG. 1B are a cross-sectional view and a conceptual diagram schematically showing a semiconductor package, respectively, according to an example embodiment, and FIG. 1C is a conceptual diagram comparing physical sizes of a high-stage semiconductor package and a low-stage semiconductor package.

Referring to FIGS. 1A to 1C, a semiconductor package 100 of the present example embodiment may include a base chip 110, a chip stack 120, a deactivation controller 130, and a sealing member 140.

The base chip 110 may be disposed at the bottom of the semiconductor package 100. The base chip 110 may be larger in size than memory chips 120-1 to 120-12 of the chip stack 120 arranged over the base chip 110. However, the size of the base chip 110 is not limited thereto. For example, the base chip 110 may have the same size as the memory chips 120-1 to 120-12.

The base chip 110 may include a substrate, a device layer, and a through silicon via (TSV) 125. The substrate may include, for example, a semiconductor element such as silicon (Si) or germanium (Ge). In some example embodiments, the substrate may include a compound semiconductor such as silicon carbide (SiC), gallium arsenide (GaAs), indium arsenide (InAs), or indium phosphide (InP). The substrate may have a silicon-on-insulator (SOI) structure. For example, the substrate may include a buried oxide (BOX) layer. The substrate may include a conductive region, for example, a well doped with impurities or a structure doped with impurities. The substrate may include various device isolation structures, for example, a shallow trench isolation (STI) structure.

In FIG. 1A, for convenience of illustration, a substrate and a device layer are shown as a single component without distinction. In an example embodiment, a device layer may be formed in a lower portion of a substrate. Further, a device layer may be distinguished into an integrated circuit layer and a multiple wiring layer. The multiple wiring layer may be connected to a first connection terminal 150.

The TSV 125 may have a structure that penetrates through the entire substrate or a portion of the substrate. The TSV 125 has a pillar-like shape and may include a barrier film on an outer surface and a buried conductive layer therein. The barrier film may include at least one material selected from among Ti, TiN, Ta, TaN, Ru, Co, Mn, WN, Ni, and NiB. The buried conductive layer may include at least one material selected from among Cu, Cu alloys such as CuSn, CuMg, CuNi, CuZn, CuPd, CuAu, CuRe, and CuW, W, W alloys, Ni, Ru, and Co. Meanwhile, a via insulation layer may be provided between the TSV 125 and the substrate or between the TVS 125 and the device layer. The via insulation layer may include, for example, an oxide film, a nitride film, a carbide film, a polymer, or a combination thereof.

The device layer may include various types of devices depending on the type of a chip. For example, the device layer may include field effect transistors (FET) such as a planar FET or a FinFET, memory devices such as a flash memory, a dynamic random access memory (DRAM), a static random access memory (SRAM), an electrically erasable programmable read-out (EPEROM). a phase-change random access memory (PRAM), a magnetoresistive random access memory (MRAM), a ferroelectric random access memory (FeRAM), and a resistive random access memory (RRAM), logic devices such as AND, OR, and NOT, and various active devices and/or passive devices such as a system large scale integration (LSI), a CMOS Imaging Sensors (CIS), and a Micro-Electro-Mechanical Systems (MEMS).

In the semiconductor package 100 according to the present example embodiment, the base chip 110 may include a plurality of logic devices in a device layer. Therefore, the base chip 110 may be referred to as a logic chip. The base chips 110 may be disposed below the chip stack 120, integrate signals of the memory chips 120-1 to 120-12, transmit integrated signals to the outside, and also transmit signals and power from the outside to the memory chips 120-1 to 120-12. Therefore, the base chip 110 may also be referred to as a buffer chip or a control chip. In contrast, the memory chips 120-1 to 120-12 of the chip stack 120 may each include a plurality of memory devices in a device layer. According to some example embodiments, the memory chips 120-1 to 120-12 may be referred to as core chips.

As described above, a device layer may include an integrated circuit layer and a multiple wiring layer. The above-stated devices may be arranged in the integrated circuit layer. The multiple wiring layer may have a multi-layer wiring structure. The wiring structure may include, for example, wires and/or vias. The wiring structure may connect devices to the first connection terminal 150. Also, the wiring structure may connect the TSV 125 to the first connection terminal 150.

The chip stack 120 is stacked on the base chip 110 and may include at least one memory chip. In the semiconductor package 100 according to the present example embodiment, the chip stack 120 may include 12 memory chips 120-1 to 120-12, for example, first to twelfth memory chips 120-1 to 120-12. However, the number of memory chips in the chip stack 120 is not limited thereto. For example, the chip stack 120 may include less than or more than 12 memory chips.

Meanwhile, memory chips of the chip stack 120 may be classified into a set number of stack-ID (SID) regions. Here, the SID region may be a concept including memory chips to be tested together. For example, in FIG. 1B, four memory chips may be included per SID region. Therefore, first to fourth memory chips 120-1 to 120-4 may be included in a first SID region SID0, fifth to eighth memory chips 120-5 to 120-8 may be included in a second SID region SID1, and ninth to twelfth memory chips 120-9 to 120-12 may be included in a third SID region SID2. However, the number of memory chips included per SID region is not limited to four. Meanwhile, SIDn (e.g., n-th SID or an SID having an SID number or SID ID number ‘n’), such as SID0, SID1, SID2, etc., may be referred to as a SID number indicating a corresponding SID region.

The memory chips 120-1 to 120-12 of the chip stack 120 may each have a structure similar to that of the base chip 110. For example, in case a first memory chip 120-1, the first memory chip 120-1 may include a substrate, a device layer, and the TSV 125. The TSV 125 may have a structure that penetrates through the substrate entirely or partially. For example, when the first memory chip 120-1 is divided into a cell region and a pad region and the TSV 125 is formed only in the pad region, the TSV 125 may be formed to penetrate through the substrate entirely. Meanwhile, the TSV 125 may not be formed in the uppermost memory chip (e.g., a twelfth memory chip 120-12).

Meanwhile, the device layer of the first memory chip 120-1 may include a plurality of memory devices. For example, the device layer may include volatile memory devices such as DRAM, SRAM, or non-volatile memory devices such as flash memory, PRAM, MRAM, FeRAM, or RRAM. In the semiconductor package 100 according to the present example embodiment, the memory chips 120-1 to 120-12 may be DRAM chips for a high bandwidth memory (HBM) package including DRAM devices in the device layer. Therefore, the semiconductor package 100 of the present example embodiment may be an HBM package.

The first memory chip 120-1 may be mounted on the base chip 110 through bonding using connection terminals, pad-to-pad bonding, hybrid bonding (HB), or bonding using an anisotropic conductive film (ACF). Here, a connection terminal may include a bump or solder, similar to the first connection terminal 150. In the case of bonding using a connection terminal, an adhesive layer or underfill may be filled between the first memory chip 120-1 and the base chip 110. Meanwhile, because pads usually include Cu, pad-to-pad bonding is also called Cu-to-Cu bonding. The HB may refer to a combination of pad-to-pad bonding and insulator-to- insulator bonding. An ACF is an anisotropic conductive film that allows electricity to flow in only one direction and may refer to a conductive film formed by mixing fine conductive particles into an adhesive resin and forming a film. Meanwhile, each of second to twelfth memory chips 120-2 to 120-12 over the first memory chip 120-1 may also be mounted on a memory chip directly below through bonding using a connection terminal, the pad-to-pad bonding, the HB, or the bonding using an ACF.

For convenience of illustration, FIG. 1A shows that the TSV 125 has a structure extending by penetrating through both the base chip 110 and the chip stack 120. However, in reality, the TSV 125 may be formed in the base chip 110 and each of first to eleventh memory chips 120-1 to 120-11. The connection between TSVs 125 of the base chip 110 and the first memory chip 120-1 and the connection between TSVs 125 of memory chips adjacent to each other may be achieved through bonding using a connection terminal, the pad-to-pad bonding, the HB, or the bonding using an ACF.

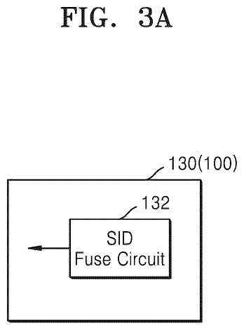

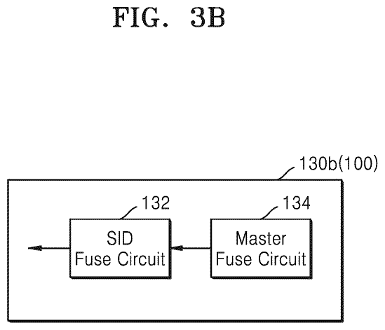

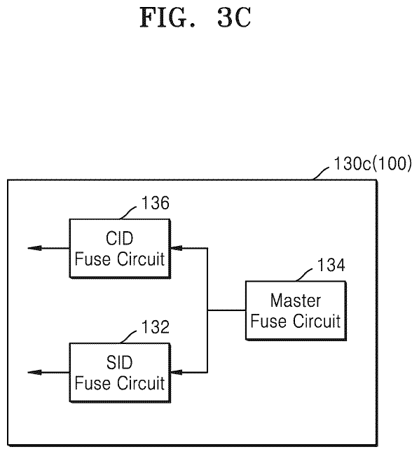

The deactivation controller 130 may deactivate memory chips SID region by SID region. Here, deactivation may mean that a corresponding memory chip is not operating. In other words, a deactivated memory chip may be ignored. In the semiconductor package 100 according to the present example embodiment, all memory chips included in one fail-SID region F-S including a fail memory chip F-C may be deactivated by the deactivation controller 130. To describe in more details with reference to FIG. 1B, when a sixth memory chip 120-6, which is the sixth chip on the base chip 110, is a fail memory chip F-C, the second SID region SID1 to which the sixth memory chip 120-6 belongs corresponds to the fail-SID region F-S, and thus, all of the fifth to eighth memory chips 120-5 to 120-8 included in the second SID region SID1 may be deactivated by the deactivation controller 130. Of course, first to fourth memory chips 120-1 to 120-4 included in the first SID region SID0 and the ninth to twelfth memory chips 120-9 to 120-12 included in the third SID region SID2 may operate normally in an activated state. The detailed structure and the operation of the deactivation controller 130 are described below in more detail with reference to FIGS. 3A to 5B.

Although FIGS. 1A and 1B show that the deactivation controller 130 is disposed on the base chip 110, the location of the deactivation controller 130 is not limited to the base chip 110. For example, the deactivation controller 130 may be disposed on the chip stack 120 or may be disposed on both the base chip 110 and the chip stack 120. According to some example embodiments, the deactivation controller 130 may be disposed in a silicon interposer on which the semiconductor package 100 is mounted or may be separately manufactured as a control chip and disposed on a package substrate on which the semiconductor package 100 is mounted.

The sealing member 140 may surround side surfaces of the chip stack 120 on the base chip 110. The sealing member 140 may not cover the top surface of the twelfth memory chip 120-12, which is the uppermost memory chip of the chip stack 120. Therefore, the top surface of the twelfth memory chip 120-12 may be exposed from the sealing member 140. However, according to some example embodiments, the scaling member 140 may cover the top surface of the twelfth memory chip 120-12 with a certain thickness. The sealing member 140 may include, for example, an epoxy mold compound (EMC). Of course, the material of the sealing member 140 is not limited to the EMC. For example, the sealing member 140 may include a photosensitive material such as Ajinomoto Build-up Film (ABF) resin, Bismaleimide Triazine (BT) resin, or Photo Imageable Encapsulant (PIE).

The first connection terminal 150 is disposed on the bottom surface of the base chip 110 and may be electrically connected to the TSV 125 through a wiring structure of a device layer. The first connection terminal 150 may include a pillar and solder. However, according to some embodiments, the first connection terminal 150 may include only solder. The pillar has a cylindrical shape and may include, for example, nickel (Ni), copper (Cu), palladium (Pd), platinum (Pt), gold (Au), or a combination thereof. The solder is provided on the pillar and may have a spherical shape or a ball-like shape. The solder may include, for example, tin (Sn), indium (In), bismuth (Bi), antimony (Sb), copper (Cu), silver (Ag), zinc (Zn), lead (Pb), and/or an alloy thereof.

In the semiconductor package 100 according to the present example embodiment, as all memory chips included in one fail-SID region F-S to which the fail memory chip F-C belongs are deactivated by the deactivation controller 130, the semiconductor package 100 is rescued and used as the semiconductor package 100 in which one SID region is omitted. Therefore, the yield of the semiconductor package 100 may be significantly improved. To described simply with specific numbers, in a 12-stage semiconductor package structure in which a chip stack includes 12 memory chips, it is assumed that there is a 10% chance that at least one memory chip within one SID region fails, a 5% chance that at least two memory chips within two SID regions fail, and a 1% chance that at least three memory chips within three SID regions fail. Typically, in a multi-stage semiconductor package structure, when any one memory chip fails, the entire semiconductor package may be considered as being defective and discarded. Therefore, in the above-stated case, about 16% of semiconductor packages may be discarded. However, in the case of the semiconductor package 100 according to the present example embodiment, when at least one memory chip within one SID region fails, only memory chips within the corresponding SID region (e.g., the fail-SID region F-S) are deactivated, and memory chips within the remaining two SID regions are activated and may be used normally as an 8-stage semiconductor package structure. As a result, 10% of 12-stage semiconductor packages may be rescued and used as 8-stage semiconductor packages. Therefore, when the number of 12-stage semiconductor packages is identical to the number of 8-stage semiconductor packages, the yield of 8-stage semiconductor packages may be increased by about 10%.

To explain more generally, the semiconductor package 100 according to the present example embodiment has a M*n (M is the number of memory chips per SID region, n is the number of SID regions, and M and n are both integers greater than or equal to 2)-stage semiconductor package structure, and, when at least one memory chip in one SID region (e.g., a fail-SID region F-S) fails, the semiconductor package may be rescued and used as an M*(n−1)-stage semiconductor package structure through deactivation of all memory chips in the fail-SID region F-S by the deactivation controller 130. For example, when M is 4, an 8-stage semiconductor package structure may be rescued and used as a 4-stage semiconductor package structure, a 12-stage semiconductor package structure may be rescued and used as an 8-stage semiconductor package structure, and a 16-stage semiconductor package structure may be rescued and used as a 12-stage semiconductor package structure.

For reference, when a semiconductor package structure including n SID regions is called a high-stage semiconductor package structure, a semiconductor package structure including n−1 SID regions is called a low-stage semiconductor package structure, and a semiconductor package structure in which all memory chips in one fail-SID region F-S in the high-stage semiconductor package structure are deactivated is called an omitted semiconductor package structure, the following conditions may need to be satisfied for the omitted semiconductor package structure to be rescued and used as a low-stage semiconductor package structure. First, all memory chips in the fail-SID region F-S need to be permanently deactivated. Second, the physical size of the omitted semiconductor package structure needs to be identical to that of the low-stage semiconductor package structure. For the second condition, the physical sizes of the omitted semiconductor package and the low-stage semiconductor package need to be identical to each other in the chip on wafer (CoW) package state, and all of the width, the length, and the height of the omitted semiconductor package need to be identical to those of the low-stage semiconductor package. Here, the CoW package state may refer to a state in which the chip stack 120 is stacked on each of a plurality of base chips 110 in a wafer state.

Referring to FIG. 1C, when a high-stage semiconductor package HSP includes three SID regions, a low-stage semiconductor package LSP includes two SID regions, and each SID region includes four memory chips, to rescue and utilize the high-stage semiconductor package HSP including one fail-SID region F-S as the low-stage semiconductor package LSP, a length L1 in the x direction, a length in the y direction, and a height H1 of the high-stage semiconductor package HSP need to be identical to those of the low-stage semiconductor package LSP. For example, as shown in FIG. 1C, an eighth memory chip, which is the uppermost memory chip in the low-stage semiconductor package LSP, may have a thickness corresponding to the combined thickness of five memory chips in the high-stage semiconductor package HSP.

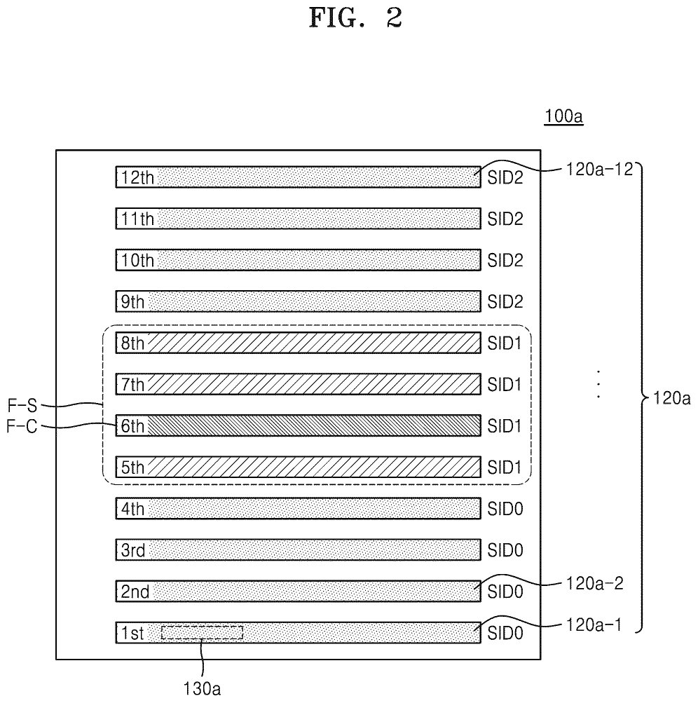

FIG. 2 is a conceptual diagram schematically showing a semiconductor package according to an example embodiment. Descriptions already given above with reference to FIGS. 1A and 1B are briefly given or omitted.

Referring to FIG. 2, a semiconductor package 100a according to the present example embodiment may differ from the semiconductor package 100 of FIG. 1B in that the semiconductor package 100a does not include a base chip. For example, the semiconductor package 100a according to the present example embodiment may include a chip stack 120a, a deactivation controller 130a, and a sealing member. FIG. 2 may correspond to FIG. 1B, and thus the sealing member is omitted in FIG. 2. In some example embodiments, the semiconductor package 100a according to the present example embodiment may be mounted on a package substrate via a first connection terminal. According to some example embodiments, the semiconductor package 100a may be defined to include a package substrate.

In the semiconductor package 100a according to the present example embodiment, the chip stack 120a may include a plurality of memory chips. For example, the chip stack 120a may include twelve memory chips 120a-1 to 120a-12. Each of the twelve memory chips 120a-1 to 120a-12 includes a cell region and a peripheral circuit region, memory devices may be arranged in the cell region, and logic devices for the operation of the memory devices may be arranged in the peripheral circuit region.

Except for the uppermost memory chip 120a-12, memory chips 120a-1 to 120a-11 may each include a TSV. As shown in FIG. 2, the deactivation controller 130a may be disposed in a first memory chip 120a-1. However, the location of the deactivation controller 130a is not limited to the first memory chip 120a-1. For example, the deactivation controller 130a may be disposed in each of the memory chips 120a-2 to 120a-12. Also, according to some example embodiments, the deactivation controller 130a may be disposed in a silicon interposer on which the semiconductor package 100a is mounted or may be separately manufactured as a control chip and disposed on a package substrate on which the semiconductor package 100a is mounted. In the semiconductor package 100a according to the present example embodiment, the deactivation controller 130a may deactivate memory chips SID region by SID region.

The semiconductor package 100a according to the present example embodiment may be, for example, a Double Data Rate (DDR) 5 or a DDR5 or later generation SDRAM (Synchronous Dynamic Random Access Memory) package (hereinafter, simply referred to as a ‘DDR5 or later generation package’). For DDR5 or later generation packages, testing may be performed SID region by SID region, similar to an HBM package. Therefore, by deactivating all memory chips in the fail-SID region F-S through the deactivation controller 130a similarly as in FIGS. 1A and 1B and rescuing a corresponding semiconductor package as a low-stage semiconductor package structure, the yield of semiconductor packages may be improved.

In semiconductor packages 100 and 100a of FIGS. 1A and 2, an HBM package and a DDR5 or later generation package have been illustrated as examples. However, a semiconductor package according to the present example embodiment is not limited to the above-stated packages. For example, the semiconductor package according to the present example embodiment may be applied to a multi-stage semiconductor package having any structure in which testing is performed SID region by SID region. Further, in the semiconductor package according to the present example embodiment, memory chips in a chip stack are not limited to DRAM chips. For example, the semiconductor package according to the present example embodiment may include a chip stack in which other memory chips, such as flash memory chips, are stacked.

FIGS. 3A to 3C are block diagrams showing a deactivation controller provided in a semiconductor package. Descriptions of FIGS. 3A to 3C are given below with reference to FIG. 1B, and descriptions already given above with reference to FIGS. 1A to 2 are briefly given or omitted.

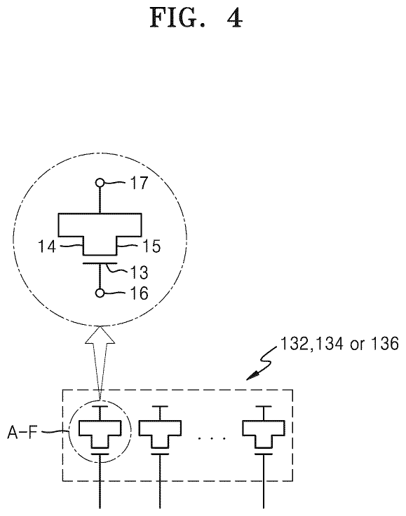

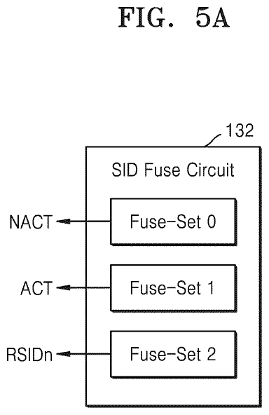

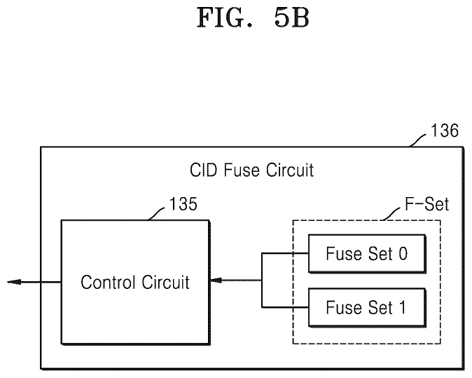

Referring to FIG. 3A, the deactivation controller 130 of the semiconductor package 100 according to the present example embodiment may include a SID fuse circuit 132. The SID fuse circuit 132 may include a plurality of fuse-sets. The fuse-sets of the SID fuse circuit 132 may be programmed to deactivate one fail-SID region F-S. In other words, an output of a programmed SID fuse circuit 132 may deactivate all memory chips in one fail-SID region F-S. Further, the SID fuse circuit 132 may reassign SID numbers (e.g., SIDn) of the SID regions. For example, when three SID regions include the first SID region SID0, the second SID region SID1, and the third SID region SID2 and the second SID region SID1 is the fail-SID region F-S, the SID fuse circuit 132 may reassign the SIDn of the third SID region SID2 from SID2 to SID1. The plurality of fuse-sets within the SID fuse circuit 132 are described below in more detail with reference to FIG. 4, and the reassignment of SIDn by the SID fuse circuit 132 is described below in more detail with reference to FIG. 5A.

Referring to FIG. 3B, a deactivation controller 130b of the semiconductor package 100 according to the present example embodiment may include the SID fuse circuit 132 and a master fuse circuit 134. The SID fuse circuit 132 and the master fuse circuit 134 may each include a plurality of fuse-sets. The master fuse circuit 134 may be a fuse circuit that determines whether to deactivate the fail-SID region F-S. For example, in the master fuse circuit 134, it may be determined whether to deactivate the fail-SID region F-S through programming of fuse-sets. Further, depending on an output of the master fuse circuit 134, fuse-sets of the SID fuse circuit 132 may be programmed to deactivate one fail-SID region F-S. In other words, when there is an output signal for deactivation of the fail-SID region F-S from the master fuse circuit 134, the SID fuse circuit 132 may perform deactivation for one fail-SID region F-S, and, when there is no output signal for deactivation of the fail-SID region F-S from the master fuse circuit 134, the SID fuse circuit 132 may not perform deactivation.

Referring to FIG. 3C, a deactivation controller 130c of the semiconductor package 100 according to the present example embodiment may include the SID fuse circuit 132, the master fuse circuit 134, and a chip-ID (CID) fuse circuit 136. The SID fuse circuit 132, the master fuse circuit 134, and the CID fuse circuit 136 may each include a plurality of fuse-sets. The CID fuse circuit 136 may change CIDs of memory chips through programming of fuse-sets. For example, when the CID fuse circuit 136 receives an output signal for deactivation of the fail-SID region F-S from the master fuse circuit 134, the CID fuse circuit 136 may change the CIDs of memory chips of a SID region located above the fail-SID region F-S.

With reference to FIG. 1B, when the sixth memory chip 120-6 fails, the second SID region SID1 is deactivated as the fail-SID region F-S through the SID fuse circuit 132, and the SIDn of the third SID region SID2 above the second SID region SID1 may be reassigned from SID2 to SID1. Further, the CID fuse circuit 136 may change the CIDs of the memory chips in a third SID region SID1. For example, when the CIDs of the ninth to twelfth memory chips 120-9 to 120-12 of the third SID region SID2 are CID9 to CID12, the CID fuse circuit 136 may change the CIDs of the ninth to twelfth memory chips 120-9 to 120-12 of the third SID region SID1 to CID5 to CID8. In this way, by reassigning the SIDn through the SID fuse circuit 132 and changing the CIDs of memory chips through the CID fuse circuit 136, a rescued high-stage semiconductor package may operate substantially identical to a low-stage semiconductor package.

For the deactivation controller, three circuit structures have been described above. However, the circuit structure of the deactivation controller is not limited to the three circuit structures described above. For example, the deactivate controller may include various other circuit structures, as long as the deactivation controller is capable of deactivating all memory chips within the fail-SID region F-S. Also, at least one of the circuit structures of the deactivation controller may not include a fuse-set.

FIG. 4 is a conceptual diagram showing fuse-sets used in the deactivation controllers of FIGS. 3A to 3C. Descriptions of FIG. 4 will be given below with reference to FIGS. 3A to 3C, and descriptions identical to those already given above with reference to FIGS. 1A to 3C will be briefly given or omitted.

Referring to FIG. 4, each or some of the SID fuse circuit 132, the master fuse circuit 134, and the CID fuse circuit 136 may be configured as an anti-fuse array including anti-fuses A-F. An anti-fuse A-F is a resistive fuse device having electrical characteristics opposite to those of a fuse device and having two resistance states. The anti-fuse A-F is generally configured in a form in which a dielectric is inserted between conductors, and, by applying a high voltage to the conductors at both ends of the anti-fuse A-F to destroy the dielectric between the two conductors, the conductors at both ends of the anti-fuse A-F are short-circuited, and thus the anti-fuse A-F may have a low resistance.

For example, as may be seen from the enlarged view of FIG. 4, the anti-fuse A-F may include a depletion type MOS transistor in which a source 14 and a drain 15 are connected to each other. In the initial state, the resistance between a first node 16 connected to a gate electrode 13 and a second node 17 commonly connected to the source 14 and the drain 15 may be very large, because the first node 16 and the second node 17 are separated from each other by a gate oxide film. Therefore, the first node 16 and the second node 17 may be in a non-conductive state, thus being in a high resistance state. Meanwhile, the anti-fuse A-F may be irreversibly changed from a non-conductive state to a conductive state by applying a breakdown voltage between the first node 16 and the second node 17 and destroying the gate oxide film. When the gate oxide film is destroyed, the resistance between the first node 16 and the second node 17 may decrease. Therefore, the first node 16 and the second node 17 may be in a conductive state and changed to a low resistance state.

Therefore, each or some of the SID fuse circuit 132, the master fuse circuit 134, and the CID fuse circuit 136 may be programmed to a desired state through a combination of resistance states of the anti-fuses A-F.

FIG. 5A is a block diagram of an SID fuse circuit in the deactivation controllers of FIGS. 3A to 3C, and FIG. 5B is a block diagram of an CID fuse circuit in the deactivation controller of FIG. 3C.

Referring to FIG. 5A, in the semiconductor package 100 according to the present example embodiment, the SID fuse circuit 132 may include three fuse-sets. However, the configuration of the SID fuse circuit 132 is not limited to the configuration of FIG. 5A. Two fuse-sets within the SID fuse circuit 132 may be programmed to deactivate all memory chips in a corresponding SID region and enable all memory chips in the remaining SID regions. For example, when the second SID region SID1 is the fail-SID region F-S, a first fuse-set Fuse-Set 0 may be programmed to deactivate all memory chips in the second SID region SID1, and a second fuse-set Fuse-Set 1 may be programmed to activate all memory chips in the remaining SID regions, that is, the first SID region SID0 and the third SID region SID2.

Meanwhile, one fuse-set in the SID fuse circuit 132, e.g., a third fuse-set Fuse-Set 2, may be programmed to reassign the SIDn of a corresponding SID region. For example, when the second SID region SID1 is the fail-SID region F-S, the third fuse-set Fuse-Set 2 may be programmed to reassign the SIDn of the third SID region SID2 to SID1. Referring to FIG. 5B, in the semiconductor package 100 according to the present example embodiment, the CID fuse circuit 136 may include two fuse-sets F-Set and a control circuit 135. However, the configuration of the CID fuse circuit 136 is not limited to the configuration of FIG. 5B. In the CID fuse circuit 136, the two fuse-sets F-Sets may be programmed to store the CID of a corresponding memory chip. For example, a first fuse-set Fuse Set 0 may store the original CID of the corresponding memory chip, and a second fuse-set Fuse Set 1 may store a CID to be changed to of the corresponding memory chip.

The control circuit 135 may provide an output of a fuse-set selected from two fuse-sets (e.g., the first fuse-set Fuse Set 0 and the second fuse-set Fuse Set 1) of the fuse-sets F-Set as the CID of the corresponding memory chip. For example, when memory chips in a fail-SID region are not deactivated, the control circuit 135 may output an output of the first fuse-set Fuse Set 0 as the CID of the corresponding memory chips, and, when memory chips in a fail-SID region are deactivated, the control circuit 135 may output an output of the second fuse-set Fuse Set 1 as the CID of the corresponding memory chips.

For reference, the CID fuse circuit 136 may determine the CID of corresponding memory chips in conjunction with a test mode register set (TMRS) that supports a test mode. The TMRS may be used at the stage of testing the CID of memory chips before programming the CID into the fuse-sets F-Set. The control circuit 135 may include a multiplexer and a selection signal generator. The selection signal generator may generate a selection signal for selecting one of CIDs provided by the first fuse-set Fuse Set 0 and the second fuse-set Fuse Set 1 of the fuse-sets F-Set and the TMRS. The multiplexer may select one of CIDs provided by the first fuse-set Fuse Set 0 and the second fuse-set Fuse Set 1 of the fuse-sets F-Set and the TMRS and output a selected CID as the CID of corresponding memory chips.

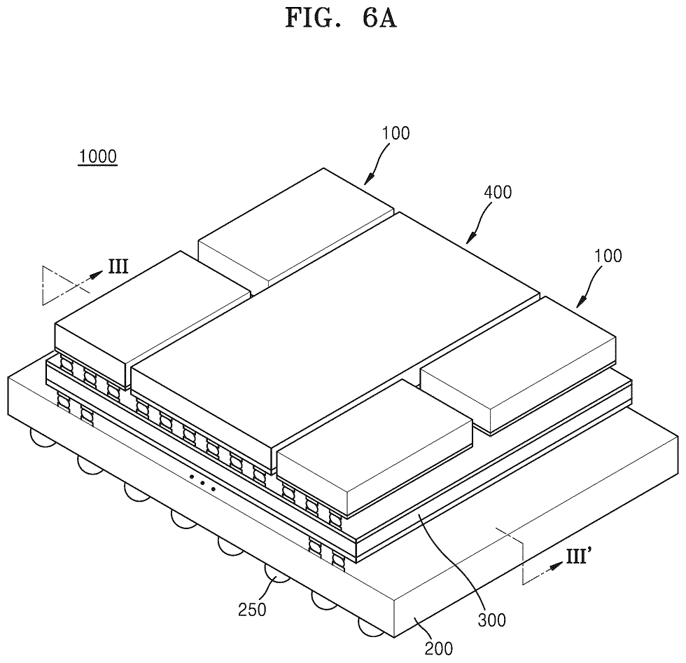

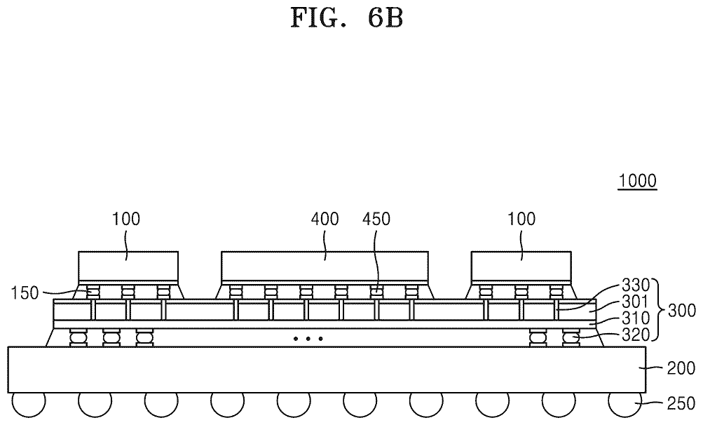

FIGS. 6A and 6B are a perspective view and a cross-sectional view of a semiconductor device including a semiconductor package. Descriptions of FIGS. 6A and 6B are given below with reference to FIG. 1B, and descriptions already given above with reference to FIGS. 1A to 5B are briefly given or omitted.

Referring to FIGS. 6A and 6B, a semiconductor device 1000 according to the present example embodiment may include a semiconductor package 100, a package substrate 200, an interposer 300, and a logic chip 400. The semiconductor package 100 may be the semiconductor package 100 of FIG. 1A. However, in the semiconductor device 1000 according to the present example embodiment, the semiconductor package 100 is not limited to the semiconductor package 100 of FIG. 1A. For example, the semiconductor package 100 may be the semiconductor package 100a of FIG. 2. In some example embodiments, the semiconductor package 100 may be a multi-stage semiconductor package having another structure in which testing is performed SID region by SID region. The semiconductor package 100 may be mounted on the interposer 300 via the first connection terminal 150. In FIG. 6A, four semiconductor packages 100 are mounted on the interposer 300, but the number of the semiconductor packages 100 is not limited to four. For example, one to three or five or more semiconductor packages 100 may be mounted on the interposer 300.

The package substrate 200 is a support substrate on which the interposer 300 is mounted and may include at least one layer of wires therein. When wires are formed in multiple layers, wires of different layers may be connected to each other through vias. According to some example embodiments, the package substrate 200 may include via electrodes directly connecting pads on the top surface and the bottom surface to each other. Although not shown, passivation layers like solder resist may be formed on the top surface and the bottom surface of the package substrate 200. Substrate pads of the package substrate 200 may be connected to wires and exposed from a protective layer.

The package substrate 200 may include, for example, a ceramic substrate, a printed circuit board (PCB), an organic substrate, an interposer substrate, etc. According to some example embodiments, the package substrate 200 may include an active wafer, such as a silicon wafer. As shown in FIG. 6A, second connection terminals 250 such as bumps or solder balls may be arranged on the bottom surface of the package substrate 200. The semiconductor device 1000 may be mounted on an external system board or a main board through the second connection terminals 250.

The interposer 300 may include an interposer substrate 301, a wiring layer 310, a bump 320, and a via electrode 330. The semiconductor package 100 and the logic chip 400 may be mounted on the package substrate 200 via the interposer 300. The interposer 300 connects the semiconductor package 100 and the logic chip 400 to each other and may also connect the semiconductor package 100 and the logic chip 400 to the package substrate 200.

The interposer substrate 301 may include, for example, any one of a silicon, organic, plastic, or glass. However, the material constituting the interposer substrate 301 is not limited to the above-stated materials. When the interposer substrate 301 is a silicon substrate, the interposer 300 may be referred to as a silicon interposer. When the interposer substrate 301 is an organic substrate, the interposer 300 may be referred to as a panel interposer. The wiring layer 310 may be disposed on the bottom surface of the interposer substrate 301. The wiring layer 310 may have a single-layer structure or a multi-layer structure.

The via electrode 330 may extend through the interposer substrate 301. Also, the via electrode 330 may extend into the wiring layer 310 and be electrically connected to wires of the wiring layer 310. When the interposer substrate 301 is silicon, the via electrode 330 may be referred to as a TSV. According to some example embodiments, the interposer 300 may include only a wiring layer therein and may not include via electrodes.

In the semiconductor device 1000 according to the present example embodiment, the interposer 300 may be used for the purpose of converting or transmitting electric signals between the semiconductor package 100 and the logic chip 400, between the package substrate 200 and the semiconductor package 100, or between the package substrate 200 and the logic chip 400. Therefore, the interposer 300 may not include components such as active devices or passive devices. The bump 320 may be disposed on the bottom surface of the interposer 300. The bump 320 may be electrically connected to the wires of the wiring layer 310. The interposer 300 may be mounted on the package substrate 200 through the bump 320.

The logic chip 400 may be a processor chip. For example, the logic chip 400 may be a GPU/CPU/SOC chip. Depending on the type of devices included in the logic chip 400, the semiconductor device 1000 may be classified into a server semiconductor device or a mobile semiconductor device. The logic chip 400 may be mounted on the interposer 300 via a third connection terminal 450.

Although not shown, the semiconductor device 1000 may include an inner sealing member that seals the semiconductor package 100 and the logic chip 400 on the interposer 300. Further, the semiconductor device 1000 may include an outer sealing member sealing the interposer 300 and the inner sealing member on the package substrate 200. According to some example embodiments, the outer sealing member and the inner sealing member may be formed together and indistinguishable. Also, according to some example embodiments, the inner sealing member may not cover the top surface of at least one of the semiconductor package 100 or the logic chip 400.

For reference, the structure of the semiconductor device 1000 as provided in the present example embodiment is referred to a 2.5D package structure, wherein the 2.5D package structure may be a relative concept to a 3D package structure without an interposer. Both the 2.5D package structure and the 3D package structure may be included in system-in-package (SIP) structures. Meanwhile, there is a package structure in which a silicon bridge of a relatively small size than the that of an interposer is disposed inside or on top of the package substrate 200 to interconnect the semiconductor package 100 and the logic chip 400. Such a structure is called a 2.3D package structure.

Also, the semiconductor device 1000 according to the present example embodiment may be a type of semiconductor package. However, because the semiconductor device 1000 includes the semiconductor package 100 corresponding to the semiconductor package 100 of FIG. 1A or 100a of FIG. 2, the entire structure is referred to as a semiconductor device to terminologically distinguish the same from the semiconductor package 100.

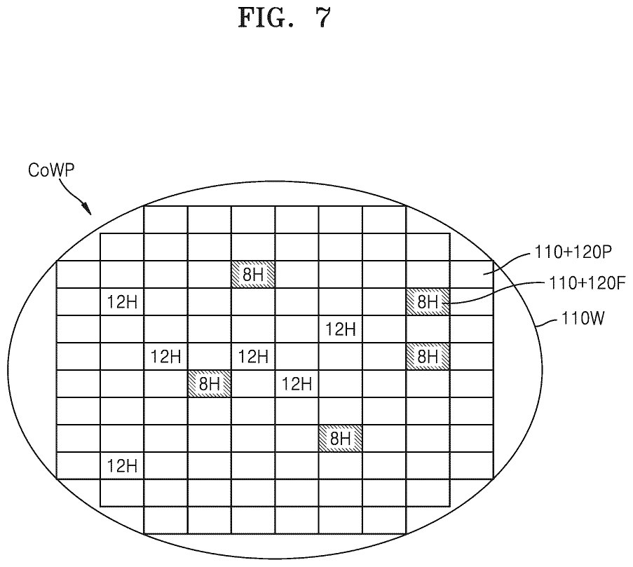

FIG. 7 is a conceptual diagram showing a CoW package (CoWP) state in which a plurality of memory chips are arranged on a wafer according to an example embodiment. Descriptions of FIG. 7 are given below with reference to FIG. 1B, and descriptions already given above with reference to FIGS. 1A to 6B are briefly given or omitted.

Referring to FIG. 7, a CoW package CoWP according to the present example embodiment may include a plurality of base chips 110 in a wafer state 100W and the chip stack 120 mounted on each of the base chips 110. The chip stack 120 may have a structure in which a plurality of memory chips are stacked. Also, the chip stack 120 may include a first chip stack 120P that does not include the fail-SID region F-S and a second chip stack 120F that includes the fail-SID region F-S.

In the CoW package CoWP according to the present example embodiment, when the chip stack 120 includes three SID regions and four memory chips per SID region, the semiconductor package 100 including the second chip stack 120F may be rescued and used as an 8-stage semiconductor package 8H. In other words, in the 8-stage semiconductor package 8H, all memory chips in one fail-SID region F-S are deactivated through the deactivation controller 130, and memory chips in the remaining SID regions may be activated and used.

The semiconductor package 100 including the first chip stack 120P may be normally used as a 12-stage semiconductor package 12H. Most of the semiconductor packages 100 that are non-hatched in FIG. 7 may be 12-stage semiconductor packages 12H. However, some of the non-hatched semiconductor packages 100 may include two or more fail-SID regions F-S. When the semiconductor package 100 includes two or more fail-SID regions F-S, the semiconductor package 100 may be discarded without being rescued.

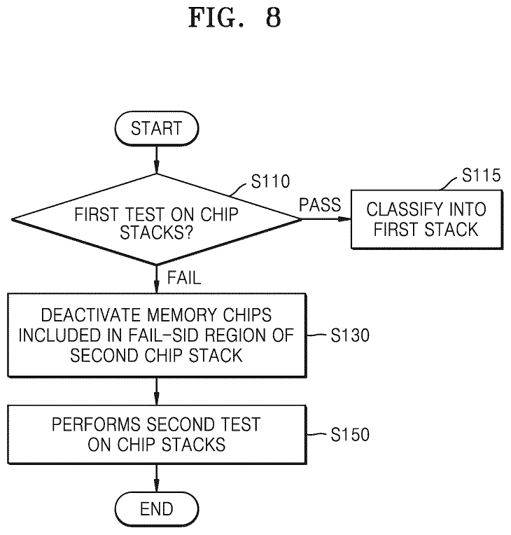

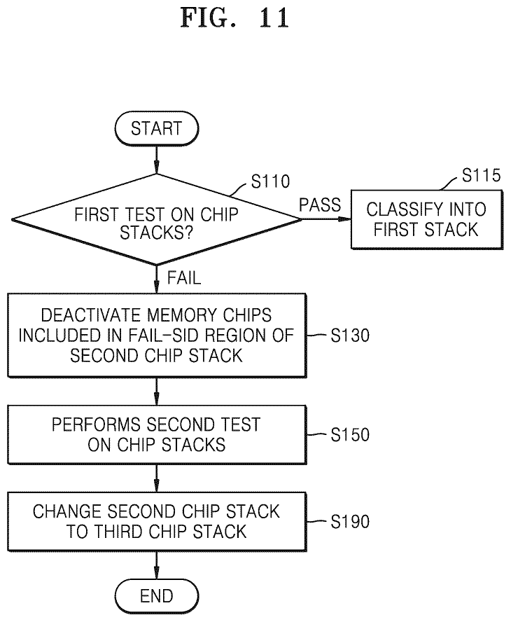

Meanwhile, in the CoW package CoWP, fail memory chips may be detected and the fail-SID region F-S may be selected through a method of testing a semiconductor package of FIGS. 8 to 10B below. The CoW package CoWP, which is a high-stage semiconductor package and includes a fail-SID region F-S, may be rescued and used as a low-stage semiconductor package according to a method of rescuing a semiconductor package of FIG. 11.

FIG. 8 is a schematic flowchart of a method of testing a semiconductor package according to an example embodiment. Descriptions of FIG. 8 will be given below with reference to FIGS. 1B and 7, and descriptions already given above with reference to FIGS. 1A to 7 will be briefly given or omitted.

Referring to FIG. 8, according to the method of testing a semiconductor package according to the present example embodiment, first, a first test on the chip stack 120 on top of each of the plurality of base chips 110 in the wafer state 100W is performed (operation S110). The first test is a characteristic test for memory chips included in the chip stack 120 and may be performed SID region by SID region. The first test may be, for example, a low frequency hot (LFH) test, which is a high temperature test from among the low frequency tests (LFT). However, the first test is not limited to the LFH test. For example, the first test could be a high frequency test (HFT).

In operation S110 of performing the first test, when the chip stack 120 passes the first test, the corresponding chip stack 120 is classified as the first chip stack 120P and stored (operation S115). In other words, when all memory chips of the chip stack 120 are determined as normal in the first test, the chip stack 120 passes the first test and may be classified as the first chip stack 120P. The first chip stack 120P that has passed the first test and the corresponding base chip 110 may be used as a high-stage semiconductor package. For example, when the chip stack 120 includes 12 memory chips, the first chip stack 120P and the base chip 110 corresponding thereto may be used as the 12-stage semiconductor package 12H.

In operation S110 of performing the first test, when the chip stack 120 fails the first test, the corresponding chip stack 120 is classified as the second chip stack 120F, and all memory chips included in the fail-SID region F-S of the second chip stack 120F are deactivated (operation S130). In other words, when at least one memory chip of the chip stack 120 is determined as fail in the first test, the chip stack 120 fails the first test and may be classified as the second chip stack 120F. Therefore, when the chip stack 120 includes a plurality of SID regions and at least one memory chip within at least one SID region is determined as fail, the corresponding chip stack 120 fails the first test and may be classified as the second chip stack 120F. Meanwhile, memory chips in the fail-SID region F-S may be deactivated through the deactivation controller 130 (e.g., the SID fuse circuit 132). Further, memory chips in SID regions other than the fail-SID region F-S may be activated through the SID fuse circuit 132. Operation S130 of deactivating memory chips in the fail-SID region F-S may also be referred to as an operation of rescuing the second chip stack 120F based on the function.

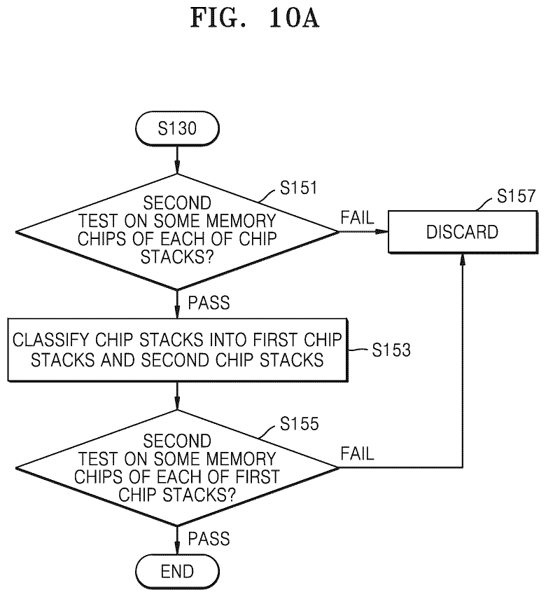

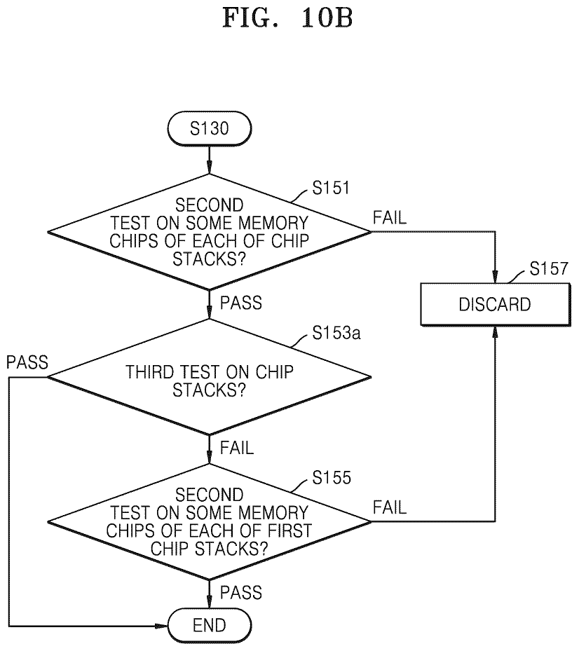

After deactivating memory chips in the fail-SID region F-S, a second test is performed on the chip stack 120 (operation S150). The second test may be a test for characteristics different from that of the first test. For example, when the first test is an LFH test among the LFTs, the second test may be a low frequency cool (LFC) test, which is a low temperature test from among the LFTs. However, the second test is not limited to the LFC test. For example, the second test may be the HFT. Detailed description of the second test will be given below with reference to FIGS. 10A and 10B.

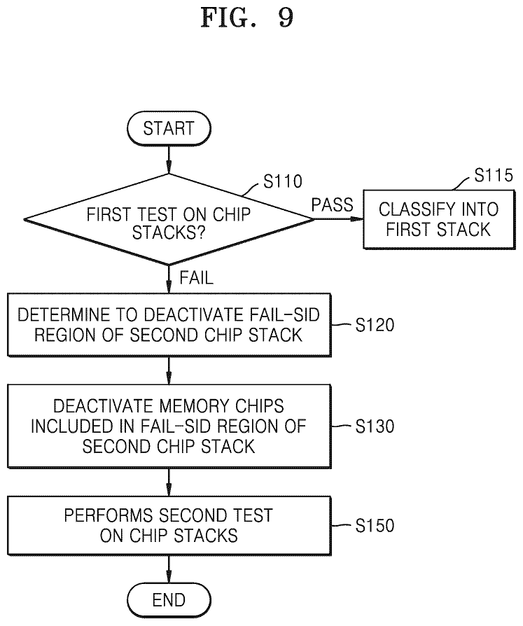

FIG. 9 is a schematic flowchart of a method of testing a semiconductor package according to an example embodiment. Descriptions of FIG. 9 will be given below with reference to FIGS. 1B and 7, and descriptions already given above with reference to FIGS. 1A to 8 will be briefly given or omitted.

Referring to FIG. 9, the method of testing a semiconductor package according to the present example embodiment may differ from the method of testing a semiconductor package of FIG. 8 in that the method according to the present example embodiment further includes operation S120 of determining whether to deactivate the fail-SID region F-S of the second chip stack 120F. According to the method of testing a semiconductor package according to the present example embodiment, first, the first test is performed on the chip stack 120 (operation S110). Operation S110 of performing the first test and the case where the chip stack 120 passes the first test are as described above for the method of testing a semiconductor package of FIG. 8.

In operation S110 of performing the first test, when the chip stack 120 fails the first test, the corresponding chip stack 120 is classified as the second chip stack 120F, and it is determined whether to deactivate the fail-SID region F-S of the second chip stack 120F (operation S120). It may be determined by the deactivation controller 130a (e.g., the master fuse circuit 134) whether to deactivate the fail-SID region F-S of the second chip stack 120F. For example, when the second chip stack 120F includes one fail-SID region F-S, in operation S120, it is determined to deactivate the fail-SID region F-S of the second chip stack 120F, and the method proceeds to operation S130 of deactivating memory chips in the fail-SID region F-S. When the second chip stack 120F includes two or more fail-SID regions F-S, in operation S120, it may be determined not to perform deactivation. When it is determined to not to perform deactivation, the semiconductor package including the second chip stack 120F may be discarded without being rescued.

Meanwhile, according to some example embodiments, even when the second chip stack 120F includes one fail-SID region F-S, in operation S120, it may be determined not to perform deactivation. In this case, when it is determined to not to perform deactivation, the semiconductor package including the second chip stack 120F may also be discarded without being rescued. Operation S120 may also be referred to as an operation of determining whether to rescue the chip stack 120 based on the function.

Operation S130 of deactivating memory chips in the fail-SID region F-S and operation S150 of performing the second test on the chip stack 120 are as described above in the method of testing a semiconductor package of FIG. 8.

Meanwhile, methods of testing a semiconductor package of FIG. 8 and/or FIG. 9 may further include an operation of verifying deactivation after operation S130 of deactivating memory chips in the fail-SID region F-S. In the operation of verifying deactivation, it may be checked whether the programmed status of the SID fuse circuit 132 is normal by applying a pattern signal to the deactivation controller 130 of the second chip stack 120F (e.g., the SID fuse circuit 132). When the programmed status of the SID fuse circuit 132 is not normal, the second chip stack 120F may be discarded. When the programmed status of the SID fuse circuit 132 is normal, the method may proceed to operation S150 of performing the second test on the chip stack 120. Here, according to some example embodiments, the operation of verifying deactivation may be referred to as the raptured (or repair) cell check mode (RCCM) operation.

FIGS. 10A and 10B are flowcharts showing the operation of performing the second test in the method of testing a semiconductor package of FIG. 8 or FIG. 9 in more detail. Descriptions of FIGS. 10A and 10B will be given below with reference to FIGS. 1B and 7, and descriptions already given above with reference to FIGS. 8 and 9 will be briefly given or omitted.

Referring to FIG. 10A, after operation S130 of deactivating memory chips in the fail-SID region F-S, in operation S150 of performing the second test on the chip stack 120, first, the second test is performed on some memory chips of each of the chip stacks 120 (operation S151). In the case of the first chip stack 120P, some of memory chips of the chip stack 120 may refer to memory chips of SID regions excluding the uppermost SID region. Also, in the case of the second chip stack 120F, some of memory chips of the chip stack 120 may refer to memory chips of SID regions excluding the fail-SID region F-S.

For example, when the chip stack 120 includes three SID regions and four memory chips per SID region, in the case of the first chip stack 120P, some of memory chips may refer to first to eighth memory chips 120-1 to 120-8 of the first SID region SID0 and the second SID region SID1 excluding the third SID region SID2. Also, in the case of the second chip stack 120F, when the second SID region SID1 is the fail-SID region F-S, some memory chips may refer to first to fourth memory chips 120-1 to 120-4 of the first SID region SID0 and the ninth to twelfth memory chips 120-9 to 120-12 of the third SID region SID2 excluding the second SID region SID1.

When the second test for some memory chips fails (Fail), the semiconductor package including the corresponding chip stack 120 is not rescued and is discarded (operation S157). When the second test for some memory chips is passed (Pass), the corresponding chip stacks 120 are classified into the first chip stack 120P and the second chip stack 120F (operation S153). As described above, the first chip stack 120P and the second chip stack 120F are mixed on the base chips 110 in a wafer state. Therefore, when the second test for some memory chips is passed, all memory chips in the second chip stack 120F may have passed the second test, and the second test may not have been performed on memory chips of the uppermost SID region of the first chip stack 120P yet. Therefore, after the chip stacks 120 are distinguished into the first chip stack 120P and the second chip stack 120F, the second test is terminated for the second chip stack 120F. In other words, in the case of the second chip stack 120F, all memory chips excluding those in the fail-SID region F-S may be determined as normal.

Meanwhile, in the case of the first chip stack 120P, it is desired to perform the second test on memory chips in the uppermost SID region. Therefore, in each of first chip stacks 120P, the second test is performed on the remaining memory chips on which the second test has not been performed (operation S155). When the second test for the remaining memory chips fails (Fail), the semiconductor package including the first chip stack 120P is not rescued and is discarded (operation S157). Also, when the second test for the remaining memory chips is passed (Pass), the second test is terminated. In other words, in the case of the first chip stack 120P, after passing the second test for the remaining memory chips, all of memory chips therein may be determined as normal, and thus the semiconductor package including the first chip stack 120P may be used as the high-stage semiconductor package HSP.

Referring to FIG. 10B, after operation S130 of deactivating memory chips in the fail-SID region F-S, in operation S150 of performing the second test on the chip stack 120, first, the second test is performed on some memory chips of each of the chip stacks 120 (operation S151). Operation S151 of performing the second test on some memory chips is as described with reference to FIG. 10A.

When the second test for some memory chips fails (Fail), the semiconductor package including the corresponding chip stack 120 is not rescued and is discarded (operation S157). When the second test for some memory chips is passed (Pass), a third test is performed on the chip stacks 120 (operation S153a). The third test may be a test to distinguish the chip stacks 120 into the first chip stack 120P and the second chip stack 120F. The third test may be performed by using the deactivation controller 130 (e.g., the SID fuse circuit 132). For example, in operation S130 of deactivating the memory chips in the fail-SID region F-S, the SID fuse circuit 132 may be programmed to deactivate the memory chips in the fail-SID region F-S, and a first pattern signal may be applied to the SID fuse circuit 132 to determine whether the SID fuse circuit 132 is normal. Therefore, by applying a second pattern signal having a phase opposite to that of the first pattern signal, the chip stacks 120 may be distinguished into the first chip stack 120P and the second chip stack 120F.

In other words, when the first pattern signal is applied to the SID fuse circuit 132, a first expected value may be output when the chip stack 120 is the first chip stack 120P and a second expected value may be output when the chip stack 120 is the second chip stack 120F. Here, the first expected value may correspond to normal activation (Pass) and the second expected value may correspond to abnormal deactivation (Fail). On the other hand, when the second pattern signal having a phase opposite to that of the first pattern signal is applied to the SID fuse circuit 132, the second expected value may be output when the chip stack 120 is the first chip stack 120P and the first expected value may be output when the chip stack 120 is the second chip stack 120F. Therefore, the second chip stack 120F passes the third test, and the first chip stack 120P fails the third test.

As described above, when the second test for some memory chips is passed, in the case of the second chip stack 120F, all chips have passed the second test. Therefore, the second test on the second chip stack 120F that has passed the third test is terminated. In other words, in the case of the second chip stack 120F, all memory chips excluding those in the fail-SID region F-S may be determined as normal.

Meanwhile, in the case of the first chip stack 120P that has failed the third test, it is desired to perform the second test on memory chips in the uppermost SID region. Therefore, in each of first chip stacks 120P, the second test is performed on the remaining memory chips on which the second test has not been performed (operation S155). When the second test for the remaining memory chips fails (Fail), the semiconductor package including the first chip stack 120P is not rescued and is discarded (operation S157). When the second test for the remaining memory chips is passed (Pass), the second test is terminated. In other words, in the case of the first chip stack 120P, after the second test for the remaining memory chips is passed, all memory chips may be determined as normal.

FIG. 11 is a schematic flowchart of a method of rescuing a semiconductor package according to an example embodiment. Descriptions of FIG. 11 will be given below with reference to FIGS. 1B and 7, and descriptions already given above with reference to FIGS. 8 to 10B will be briefly given or omitted.

Referring to FIG. 11, in the method of rescuing a semiconductor package according to the present example embodiment, first, the method of testing a semiconductor package of FIG. 8 is sequentially performed. In other words, operations from operation S110 of performing a first test on the chip stack 120 to operation S150 of performing a second test on the chip stack 120 are performed sequentially. The operations from operation S110 of performing the first test on the chip stack 120 to operation S150 of performing the second test on the chip stack 120 are as described above in the method of testing a semiconductor package of FIG. 8. Instead of the method of testing a semiconductor package of FIG. 8, the method of testing a semiconductor package of FIG. 9 may be applied. Also, operation S150 of performing the second test on the chip stack 120 may include operations S151, S153 or S153a, S155, and S157 of FIG. 10A or FIG. 10B.

After operation S150 of performing the second test on the chip stack 120, the second chip stack 120F is changed to a third chip stack (operation S190). Changing to the third chip stack may be performed by the SID fuse circuit 132 and the CID fuse circuit 136 of the deactivation controller 130b. For example, the SIDn of a SID region above the fail-SID region F-S of the second chip stack 120F may be reassigned through the SID fuse circuit 132. Also, through the CID fuse circuit 136, the CID of memory chips in the SID region above the fail-SID region F-S of the second chip stack 120F may be changed. Therefore, the high-stage semiconductor package HSP including one fail-SID region F-S is rescued and may operate substantially identical to the low-stage semiconductor package LSP.

With reference to FIG. 1B, when the sixth memory chip 120-6 fails, the second SID region SID1 is deactivated as the fail-SID region F-S through the SID fuse circuit 132, and the SIDn of the third SID region SID2 above the second SID region SID1 may be reassigned from SID2 to SID1. The CID fuse circuit 136 may change the CIDs of the memory chips in a third SID region SID1. For example, when the CIDs of the ninth to twelfth memory chips 120-9 to 120-12 of the third SID region SID2 are CID9 to CID12, the CID fuse circuit 136 may change the CIDs of the ninth to twelfth memory chips 120-9 to 120-12 of the third SID region SID1 to CID5 to CID8. In this way, by reassigning the SIDn through the SID fuse circuit 132 and changing the CIDs of memory chips through the CID fuse circuit 136, a rescued high-stage semiconductor package may operate substantially identical to a low-stage semiconductor package.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts have been particularly shown and described with reference to some example embodiments thereof, it will be understood that various changes in form and details may be made therein without departing from the spirit and scope of the following claims.

1. A semiconductor package comprising:
a base chip;
a plurality of memory chips stacked on the base chip; and
a deactivation controller configured to deactivate the memory chips,
wherein the memory chips are classified into at least two stack-ID (SID) regions,
each of the at least two SID regions comprises a subset of the plurality of memory chips, and
when a fail-SID region including a failed memory chip, from among the at least two SID regions, exists, the deactivation controller is configured to deactivate all memory chips included in the fail-SID region and activate memory chips in remaining SID regions other than the fail-SID region.

2. The semiconductor package of claim 1, wherein, when each of the at least two SID regions comprises four memory chips, an SID region having n as an SID number (SIDn) among the at least two SID regions includes memory chips of a (4n+1)-th layer to a (4n+4)-th layer, where n is an integer of 0 or more.

3. The semiconductor package of claim 2, wherein when a number of the memory chips is 4(n+2), the deactivation controller is configured to deactivate the four memory chips in the fail-SID region and activate 4(n+1) memory chips.

4. The semiconductor package of claim 3, wherein the deactivation controller is configured to exclude the fail-SID region and reassign the SID number of a SID region above the fail-SID region.

5. The semiconductor package of claim 3, wherein, when a number of the memory chips is 12, the at least two SID regions include SID0, SID1, and SID2, and when the fail-SID region is the SID1,
the deactivation controller is configured to
deactivate the memory chips from fifth to eighth layers on the base chip and belonging to the SID1,
activate the memory chips from first to fourth layers and the memory chips from ninth to twelfth layers, the first to fourth layers being on the base chip and belonging to the SID0, the ninth to twelfth layers being on the base chip and belonging to the SID2, and
reassign the SID2 to the SID1.

6. The semiconductor package of claim 1, wherein the deactivation controller comprises at least one fuse circuit configured to deactivate all memory chips included in the fail-SID region.

7. The semiconductor package of claim 6, wherein the deactivation controller comprises:
a first fuse circuit configured to determine whether to deactivate the memory chips of the fail-SID region; and
a second fuse circuit configured to deactivate the memory chips in the fail-SID region, activate the memory chips in remaining SID regions, and reassign an SID number of a SID region above the fail-SID region.

8. The semiconductor package of claim 7, wherein the second fuse circuit is configured to test memory chips that are all normal and belong to an uppermost SID region.

9. The semiconductor package of claim 1, wherein the deactivation controller comprises a fuse circuit configured to change a chip-ID (CID) of each memory chip within the SID region above the fail-SID region.

10. The semiconductor package of claim 1, wherein, when a number of the memory chips is 4(n+2), the deactivation controller is configured to reassign an SID number and change a CID to cause the semiconductor package to operate identically to a first semiconductor package comprising 4(n+1) memory chips, where n is an integer of 0 or more.

11. The semiconductor package of claim 10, wherein a size of the semiconductor package is identical to that of the first semiconductor package.

12. The semiconductor package of claim 1, wherein the base chip comprises a buffer chip and the semiconductor package is a high bandwidth memory (HBM) package.

13. A semiconductor package comprising:
a base chip;
a plurality of memory chips stacked on the base chip; and
a fuse circuit configured to deactivate the memory chips,
wherein the memory chips are classified into at least two stack-ID (SID) regions,
each of the at least two SID regions comprises four memory chips, and
when a fail-SID region including a fail memory chip, from among the at least two SID regions, exists, the fuse circuit is configured to deactivate all four memory chips included in the fail-SID region and activate memory chips in remaining SID regions.

14. The semiconductor package of claim 13, wherein the fuse circuit comprises:
a first fuse circuit configured to determine whether to deactivate the memory chips of the fail-SID region; and
a second fuse circuit configured to deactivate the memory chips in the fail-SID region, activate the memory chips in remaining SID regions, and reassign an SID number of an SID region above the fail-SID region.

15. The semiconductor package of claim 14, wherein the fuse circuit further comprises a third fuse circuit configured to change a chip-ID (CID) of each memory chip within an SID region above the fail-SID region.

16. The semiconductor package of claim 15, wherein, when a number of the plurality of memory chips is 4(n+2), where n is an integer of 0 or more,
the semiconductor package is configured to operate identically to a first semiconductor package comprising 4(n+1) memory chips through deactivation and reassignment of the SID number by the second fuse circuit and changing of the CID by the third fuse circuit, and
a size of the semiconductor package is identical to that of the first semiconductor package.

17. A semiconductor package comprising:
a package substrate;
an intermediate substrate on the package substrate;
a logic semiconductor device on the intermediate substrate; and
at least one first semiconductor package on the intermediate substrate and being adjacent to the logic semiconductor device,
wherein the first semiconductor package comprises
a plurality of memory chips classified into at least two SID regions, and
a fuse circuit configured to deactivate memory chips in one stack-ID (SID) region and activate memory chips in remaining SID regions.

18. The semiconductor package of claim 17, wherein
the first semiconductor package comprises
a base chip,
the plurality of memory chips stacked on the base chip, and
the fuse circuit configured to deactivate the memory chips,
each of the at least two SID regions comprises four memory chips, and
when a fail-SID region including a failed memory chip, from among the at least two SID regions, exists,, the fuse circuit is configured to deactivate all memory chips included in the fail-SID region, and activate memory chips in remaining SID regions other than the fail-SID region.

19. The semiconductor package of claim 18, wherein the fuse circuit comprises:
a first fuse circuit configured to determine whether to deactivate memory chips of the fail-SID region;
a second fuse circuit configured to deactivate the memory chips in the fail-SID region, activate memory chips in remaining SID regions, and reassign an SID number of an SID region above the fail-SID region; and
a third fuse circuit configured to change a chip-ID (CID) of each memory chip within an SID region above the fail-SID region.

20. The semiconductor package of claim 19, wherein
when a number of the memory chips is 4(n+2), the semiconductor package is configured to operate identically to a first semiconductor package comprising 4(n+1) memory chips through deactivation and reassignment of an SID number by the second fuse circuit and changing of a CID by the third fuse circuit, where n is an integer of 0 or more, and
a size of the semiconductor package is identical to that of the first semiconductor package.

21-26. (canceled)
